(19) United States
(12) Patent Application Publication
(10) Pub. No.: US 2006/0096851 A1
(43) Pub. Date: May 11, 2006

(54) Physical vapor deposition chamber having an adjustable target

(76) Inventors: Ilya Lavitsky, San Francisco, CA (US); Michael Rosenstein, Sunnyvale, CA (US); Goichi Yoshidome, Narita-shi (JP); Hougong Wang, Pleasanton, CA (US); Zhendong Liu, San Jose, CA (US); Mengqi Ye, Santa Clara, CA (US)

Correspondence Address: PATTERSON & SHERIDAN, LLP;APPLIED MATERIALS INC, 595 SHREWSBURY AVE, SUITE 100, SHREWSBURY, NJ, 07702, US

(21) Appl. No.: 10/984,291

(22) Filed: Nov. 8, 2004

(51) Int. Cl. C23C 14/32; C23C 14/00

(52) U.S. Cl. 204/192.1; 204/298.23; 204/298.28

(57) ABSTRACT

The invention relates to physical vapor deposition (PVD) chambers having a rotatable substrate pedestal and at least one moveable tilted target. Embodiments of the invention facilitate deposition of highly uniform thin films.

### RELATED APPLICATIONS

This application is related to contemporaneously filed U.S. patent application Ser. No. ______, entitled PHYISCAL VAPOR DEPOSITION CHAMBER HAVING A ROTATABLE SUBSTRATE PEDESTAL, by Lavitsky, et al., (Attorney Docket No. 8414/CPI/L/B/PJS), which is incorporated by reference in its entirety.

### BACKGROUND OF THE INVENTION

1. Field of the Invention

Embodiments of the present invention generally relate to semiconductor substrate processing systems. More specifically, the invention relates to a physical vapor deposition chamber of a semiconductor substrate processing system.

2. Description of the Related Art

Physical vapor deposition (PVD), or sputtering, is one of the most commonly used processes in fabrication of integrated circuits and devices. PVD is a plasma process performed in a vacuum chamber where negatively biased target (typically, a magnetron target) is exposed to a plasma of an inert gas having relatively heavy atoms (e.g., argon (Ar)) or a gas mixture comprising such inert gas. Bombardment of the target by ions of the inert gas results in ejection of atoms of the target material. The ejected atoms accumulate as a deposited film on a substrate is placed on a substrate pedestal disposed below the target.

One critical parameter of a PVD process is the thickness non-uniformity of the deposited film. Many improvements have been introduced to reduce the film non-uniformity. Such improvements conventionally relate to design of the target (e.g., target material composition, magnetron configuration, and the like) and the vacuum chamber. However, such means alone cannot address the increasingly strict requirements for film uniformity.

Therefore, there is a need in the art for an improved PVD chamber.

### SUMMARY OF THE INVENTION

The present invention generally is a PVD chamber for depositing highly uniform thin films. The chamber includes a rotatable substrate pedestal. In one embodiment, the pedestal, during a film deposition, rotates at an angular velocity of about 10 to 100 revolutions per minute (RPM). In further embodiments, one or more sputtering targets are movably disposed above the pedestal. The orientation of the targets relative to the pedestal may be adjusted laterally, vertically or angularly. In one embodiment, the target may be adjusted between angles of about 0 to about 45 degrees relative to an axis of pedestal rotation.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of one embodiment of a PVD chamber having a rotatable substrate pedestal;

FIG. 2 is a schematic sectional view of another embodiment of a PVD chamber having a rotatable substrate pedestal;

FIGS. 2A-B are schematic sectional views of PVD chambers having a target in different processing positions;

FIG. 3A is a partial cross-sectional view of the rotatable substrate pedestal of FIG. 1;

FIG. 3B is a top view of the substrate support pedestal of FIG. 1; and

FIG. 4 is a schematic perspective view of another PVD chamber having a plurality of angled sputtering targets disposed around a rotatable substrate pedestal.

To facilitate understanding, identical reference numerals have been used, where possible, to designate identical elements that are common to the figures.

### DETAILED DESCRIPTION

The present invention generally is a PVD chamber for depositing highly uniform thin films. The improvement in film deposition uniformity is enabled, at least in part, by a rotatable substrate support pedestal.

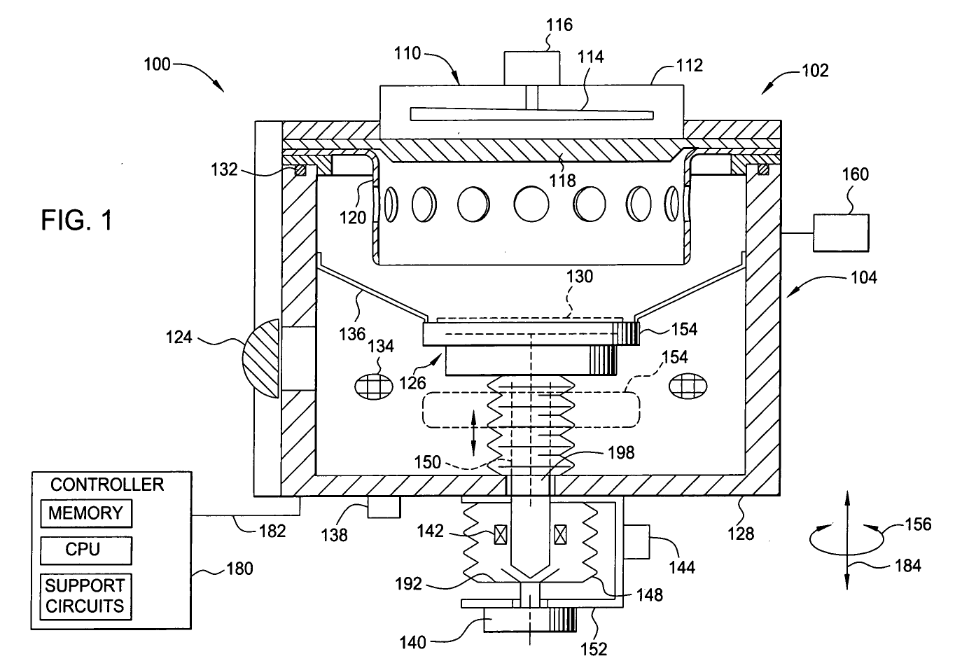

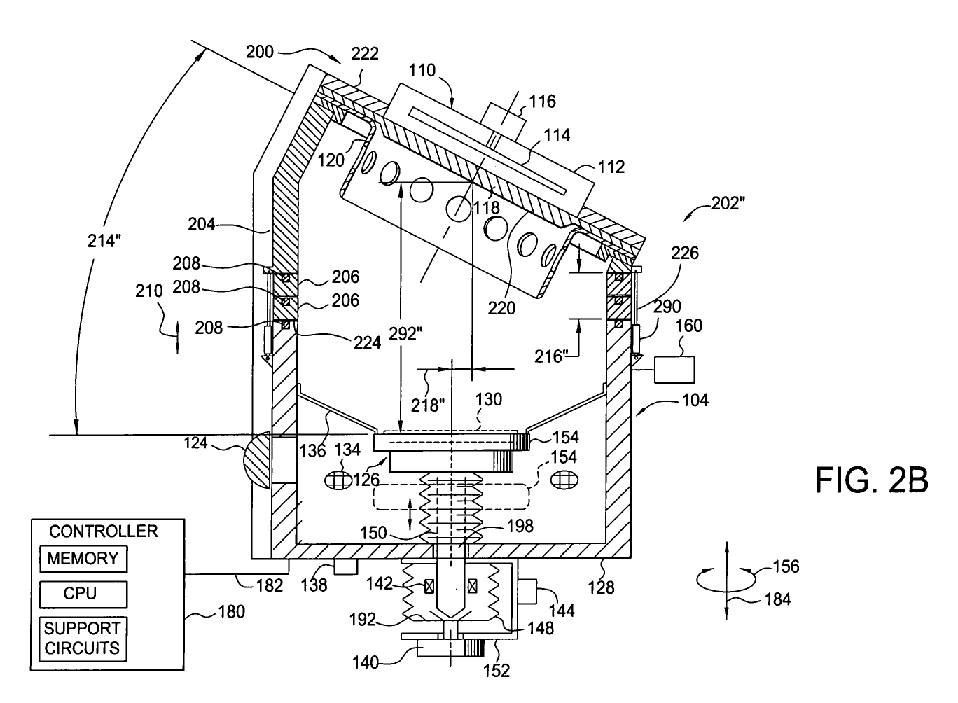

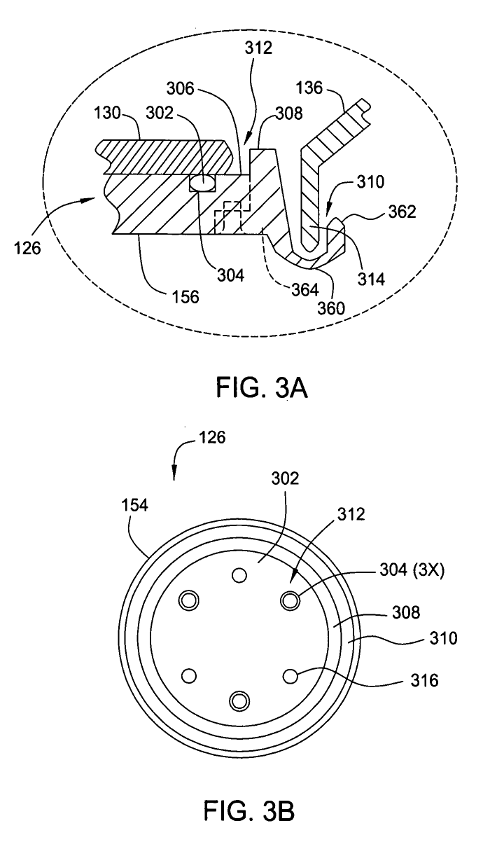

FIG. 1 depicts one embodiment of a PVD chamber 100 having a rotatable substrate pedestal 126. FIG. 3 depicts a partial cross-sectional view of the substrate pedestal 126. The cross-sectional view in FIG. 3 is taken along a radius of the substrate pedestal 126. The images in FIGS. 1 and 3 are simplified for illustrative purposes and are not depicted to scale. For best understanding of this embodiment of the invention, the reader should refer simultaneously to FIGS. 1 and 3.

The PVD chamber 100 generally comprises a lid assembly 102, a main assembly 104, a motion control unit 170, support systems 160, and a controller 180. In one embodiment, the lid assembly 102 includes a target assembly 110 and an upper enclosure 122. The target assembly 110 includes a rotatable magnetron pack 114 disposed within a target base 112 (e.g., water-cooled base), a target 118, and a target shield 120. The magnetron pack 114 is mechanically coupled to a drive 116 that, in operation, rotates the pack at a pre-determined angular velocity. One magnetron pack that may be adapted to benefit from the invention is described in U.S. Pat. No. 6,641,701, issued Nov. 4, 2003 to A. Tepman, and is incorporated herein by reference in its entirety. The target assembly 110 is electrically coupled to a plasma power supply (not shown), such as an RF, DC, pulsed DC, and the like power supply.

In one embodiment, the main assembly 104 includes a chamber body 128, the rotatable substrate pedestal 126, an inverted shield 136 circumferentially attached to the body 128, and a plurality of radiant heaters 134. The shield 136 generally extends from the upper portion of the member body 128 downward and inward toward the pedestal 126. The substrate pedestal 126 includes a substrate platen 154 and a column module 150 that are coupled to one another. Vacuum-tight coupling between the lid assembly 102 and the main assembly 104 is illustratively provided by at least one seal, of which an o-ring 132 is shown.

A substrate 130 (e.g., silicon (Si) wafer, and the like) is introduced into and removed from the PVD chamber 100 through a slit valve 124 in the chamber body 128. The radiant heaters 134 (e.g., infrared (IR) lamps, and the like) are generally used to pre-heat the substrate 130 and/or internal parts of the chamber 100 to a temperature determined by a specific process recipe. As the radiant heaters 134 are positioned below the shield 136, the heaters 134 are protected from deposition of the sputtered target material that may adversely affect heater performance.

In operation, the platen 154 may be selectively disposed in an upper processing position (as shown) or in a lower transfer position (shown in phantom). During wafer processing (i.e., sputter deposition), the platen 154 is raised to the upper position located at a pre-determined distance from the target 118. To receive or release the substrates 130, the platen 154 is moved to the lower position substantially aligned with the slit valve 124 to facilitate robotic transfer of the substrate.

Referring to the embodiment depicted in FIGS. 3A-B, the platen 154 includes at least one polymer member disposed in an upper substrate supporting surface 306 of the platen 154. The polymer member may be a suitable plastic or elastomer. In one embodiment, the polymer member is an o-ring 302 disposed in a groove 304. In operation, friction between the substrate 130 and the o-ring 302 prevents the wafer from slipping along a substrate supporting surface 186 of the rotating platen 154. Three o-rings 302 are shown in the top view of the pedestal 126 of FIG. 3B spaced between lift pin holes 316. Alternatively, a single o-ring 302 as shown in FIG. 3A may be disposed along the perimeter of the supporting surface 306 to prevent the substrate from slipping as the substrate rotates during processing.

The platen 154 additionally includes an annular peripheral rim 308 extending upward from the surface 306 and an annular peripheral and upwardly facing trench 310. The rim 308 defines a substrate receiving pocket 312 in the surface 306 that provides additional protection from substrate slippage at higher angular velocities of the platen 154. In a further embodiment (not shown), the rim 308 may be chamfered, angled, rounded or otherwise adapted to guide the substrate 130 for positioning with a minimal offset from a center of the platen 154.

In one embodiment, in the upper position of the substrate pedestal 126, the peripheral trench 310 interleaves with a downwardly extending inner lip 314 of the inverted shield 136, thus forming a trap for a peripheral flux of the sputtered target material. Such a trap protects the radiant heaters 134 from sputter deposition and extends operational life of the heaters (e.g., IR lamps). The trench 310 includes a bottom member 360 and an upwardly extending finger 362. The bottom member 360 and finger 362 may optionally be coupled to the platen 154 as a replaceable member 364 (as shown in phantom).

In alternate embodiments (not shown), the platen 154 may comprise a clamp ring, an electrostatic chuck, embedded substrate heaters, passages for backside (i.e., heat exchange) gas and/or cooling fluid, radio-frequency electrodes, and other means known to enhance a PVD process. Coupling to the respective sources (not shown) of the backside gas, cooling fluid, and electric and radio-frequency power may be accomplished using a conventional means known to those skilled in the art.

Returning to FIG. 1, the motion control unit 170 generally includes bellows 148, a magnetic drive 144, a displacement drive 140, and a lift pins mechanism 138 that are illustratively mounted on a bracket 152 attached to the chamber body 128. The bellows 148 provide an extendable vacuum-tight seal for the column module 150 that is rotateably coupled (illustrated with an arrow 156) to a bottom plate 192 of the bellows. A vacuum-tight interface between the bracket 152 and the chamber body 128 may be formed using, e.g., one or more o-rings or a crushable copper seal (not shown).

The column module 150 includes a shaft 198 and a plurality of magnetic elements 142 disposed proximate to the magnetic drive 144. In operation, the magnetic drive 144 includes a plurality of stators that may be selectively energized to magnetically rotate the magnetic elements 142, thereby rotating column module 150 and the platen 154. In one exemplary embodiment, the angular velocity of the substrate pedestal 126 is selectively controlled in a range of about 10 to 100 revolutions per minute. It is contemplated that the magnetic drive may be replaced by other motors or drives suitable for rotating the pedestal.

In operation, the flux of the material sputtered from the target 118 is spatially non-uniform because of variations in the material composition of the target, accumulation of contaminants (e.g., oxides, nitrides, and the like) on the target, mechanical misalignments in the lid assembly 102, and other factors. During film deposition in the PVD chamber 100, the rotational motion of the substrate pedestal 126 compensates for such spatial non-uniformity of the flux of the sputtered material and deposit, on the rotating substrate 130, highly uniform films. For example, variation in sputtered material from different regions of the target 118 are averaged across substrate 130 as it rotates, thus resulting in high thickness uniformity of the deposited films.

The displacement drive 140 is rigidly coupled to the bottom plate 192 of the bellows 148 and, in operation, facilitates moving (illustrated with an arrow 184) the substrate pedestal 126 between the lower (i.e., wafer receiving/releasing) position and the upper (i.e., sputtering) position. The displacement drive 140 may be a pneumatic cylinder, hydraulic cylinder, motor, linear actuation or other device suitable for controlling the elevation of the pedestal 126.

The support systems 160 comprise various apparatuses that, collectively, facilitate functioning of the PVD chamber 100. Illustratively, the support systems 160 include one or more sputtering power supplies, one or more vacuum pumps, sources of a sputtering gas and/or gas mixture, control instruments and sensors, and the like known to those skilled in the art.

The controller 180 comprises a central processing unit (CPU), a memory, and support circuits (none is shown). Via an interface 182, the controller 180 is coupled to and controls components of the PVD chamber 100, as well as deposition processes performed in the chamber.

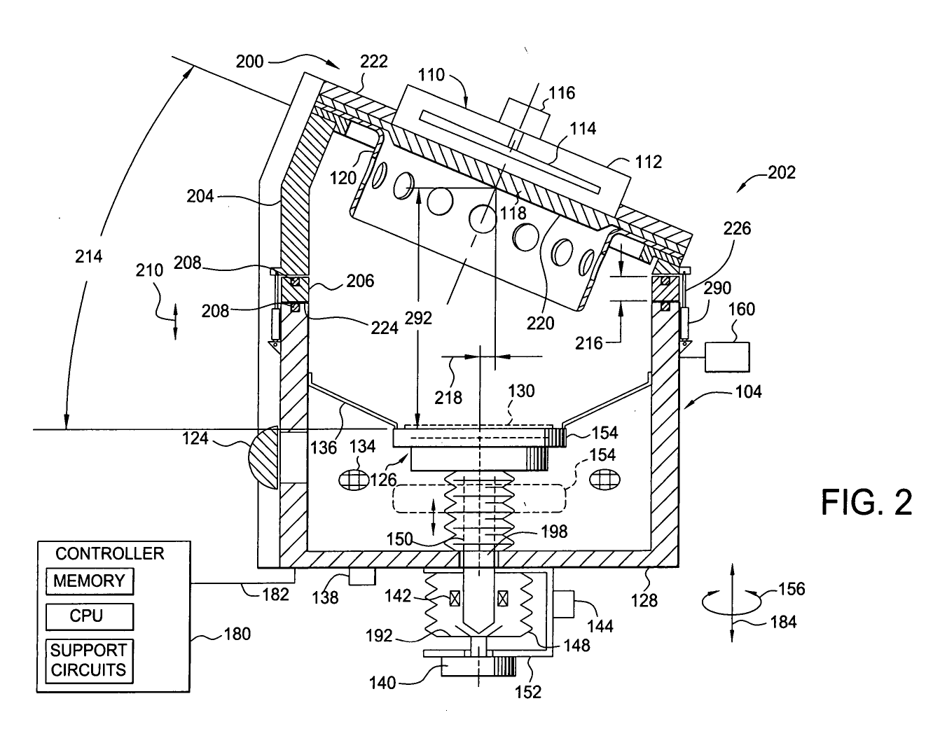

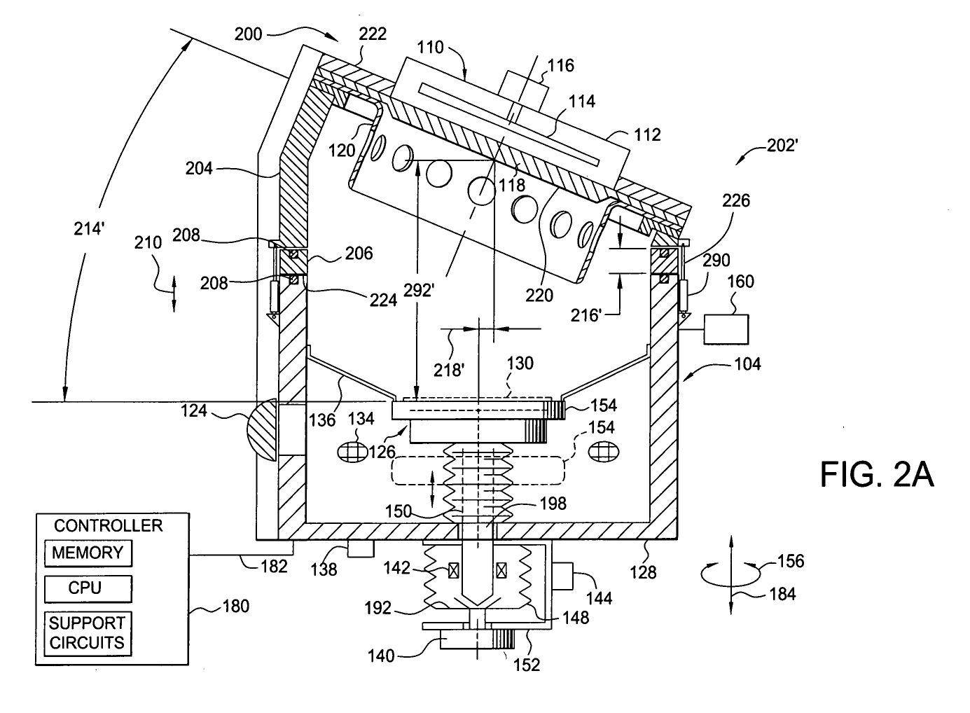

FIG. 2 depicts a schematic front view of another embodiment of a PVD chamber 200 having a rotatable substrate pedestal and a sputtering target disposed at an angle to an axis of rotation of the pedestal. The image of FIG. 2 is simplified for illustrative purposes and is not depicted to scale.

The PVD chamber 200 generally includes a lid assembly 202, the main assembly 104, the motion control unit 170, the support systems 160, and the controller 180. Components that are substantially common to the PVD chambers 100 and 200 have been discussed above in reference to FIGS. 1 and 3.

The lid assembly 202 generally comprises the target assembly 110, a tilted upper enclosure 204, and, optionally, at least one spacer 206 (one spacer is shown) mounted between the enclosure 204 and the chamber body 128. Illustratively, vacuum-tight coupling between the lid assembly 202, spacers 206, and the main assembly 104 is provided by using one or more scales 208.

The target assembly 110 is mounted in the upper enclosure 204 in a tilted position such that an angle 214 is formed between a sputtering surface 220 of the target 118 and the supporting surface 186 of the rotatable substrate pedestal 126 (or substrate 130). The center of sputtering surface 220 is vertically spaced a distance 280 from the substrate 130. The center of the sputtering surface may additionally be laterally spaced a distance 218 from the center of the substrate 130. For example, the distance 218 may be selectively set between about zero to about 450 mm. A top panel 222 of the upper enclosure 204 is generally oriented, such that the angle 214 may be selected in a range from about 0 to about 45 degrees. The tilted target causes sputtered material to impact the substrate at an inclined (i.e., non-perpendicular) incidence, thereby improving conformal deposition. As the pedestal rotates during deposition, deposition material is deposited on the substrate surface through 360 degrees. The optimum angle 214 may be determined for each type of target material and/or substrate surface topography, for example, through pre-production testing. Once optimum angles 214 are determined, the lid assembly 202 (and target 118) may be inclined at an appropriate angle for each deposition process run.

The spacers 206 may be used to define the optimal vertical distance (illustrated with an arrow 210) between the target 118 and the substrate 130. In one embodiment, a combined height 216 of the optional spacer(s) 206 may selected in a range from greater than about 0 to 500 mm. This allows a distance 292 spacing the center of the target 118 and the substrate 130 to be selected between about 200 to about 450 mm when the substrate pedestal 154 is in the raised, processing position. Similarly to the angle of target inclination, the spacers 206 may be adjusted to determine the optimal spacing between the substrate and target to achieve best processing results for different target materials and/or substrate topographies. Once the optimum distances are determined, the appropriate number and slack height of the spacers 206 may be utilized to produce optimum deposition results for each process run.

In further embodiment, the lid assembly 202 may be moved along a flange 224 of the main assembly 104 (illustrated with an arrow 212) to adjust the lateral offset between the target 118 and the substrate 130 to enhance deposition performance. In one embodiment, after restoring an atmospheric pressure in the PVD chamber 200, the lid assembly 202 may be raised above the flange 224 using a plurality of pushers 226 having low-friction tips or balls. Alternatively, the pushers 226 may formed from or include a low-friction material (e.g., TEFLON®, polyamide, and the like).

In one embodiment, actuators 290 are coupled to the main assembly 104 to selectively extend the pushers 226 above the top surface of the main assembly 104. The actuators 290 may be a fluid cylinder, an electric motor, solenoid, cam or other suitable device for displacing the pusher 226 to separate the lid assembly 202 from the main assembly 104. Although the actuators 290 are shown coupled to the main assembly 104, it is contemplated that the actuators 290 may be coupled to the lid assembly 202 and configured to extend the pushers 226 downward from the lid assembly 202 to lift the lid assembly 202 from the main assembly 104.

In the raised position, the lid assembly 202 may be moved along the flange 224 to a pre-determined position, where the pushers 226 are lowered and vacuum-tight coupling between the lid and main assemblies is restored. In one embodiment, a distance (or offset) 218 of the sliding movement of the lid assembly 202 may selectively be controlled in a range from about 0 to 500 mm. Similarly to the angle and height (spacing) adjustments, the offset between the target 118 and substrate may be selected, in combination with the angle and height, to optimize deposition results for different materials and substrate topographies.

Generally, optimal values of the angle 214, height 216 (spacing 292), and offset 218 that collectively define, with respect to the rotatable substrate pedestal 126, a spatial position of the target assembly 110 and, as such, an angle of incidence and kinetic energy of atoms the sputtered target material, may be process-specific. In operation, when the target assembly 110 is located in the process-specific optimal spatial position, films having the best properties (e.g., minimal thickness non-uniformity) may be deposited on the substrate 130. Thus, once the optimum angle, spacing and offset are known for predetermined deposition materials and/or substrate topographies the orientation of the lid assembly 202 and target 118 may be set in a predefined orientation to produce a desired process result for a predetermined process run. For illustration, FIGS. 2A-B depict the lid assembly 202 having different angles 214′, 214″, vertical spacing 292′, 292″ and lateral offset 218′, 218″.

In one exemplary embodiment, the invention was reduced to practice using elements of PVD chambers of the Endura CL® integrated semiconductor wafer processing system available from Applied Materials, Inc. of Santa Clara, Calif. In this embodiment, aluminum (Al), tantalum (Ta), copper (Cu), and nickel-iron (Ni—Fe) alloy films were deposited, using respective magnetron targets, on 300 mm silicon (Si) wafers rotating at about 48 revolutions per minute. By optimizing the angle 214, height 216 (spacing 292), and offset 218 within the process-specific ranges of about 30 degrees, 340-395 mm, and 300-400 mm, respectively, the thickness non-uniformity of about 0.17-0.35% (1σ) has been achieved for the deposited films, as shown in a table below.

| | 1σ, | Angle 214, | Height 216, | Offset 218, |
|---|---|---|---|---|
| Material | % | degrees | mm | mm |
| Aluminum | 0.22-0.27 | 30° | 350-370 | 320-400 |
| Tantalum | 0.17-0.23 | 30° | 350-375 | 375-400 |
| Copper | 0.16-0.29 | 30° | 340-365 | 380-385 |
| Nickel-Iron | 0.24-0.35 | 30° | 350-370 | 340-360 |

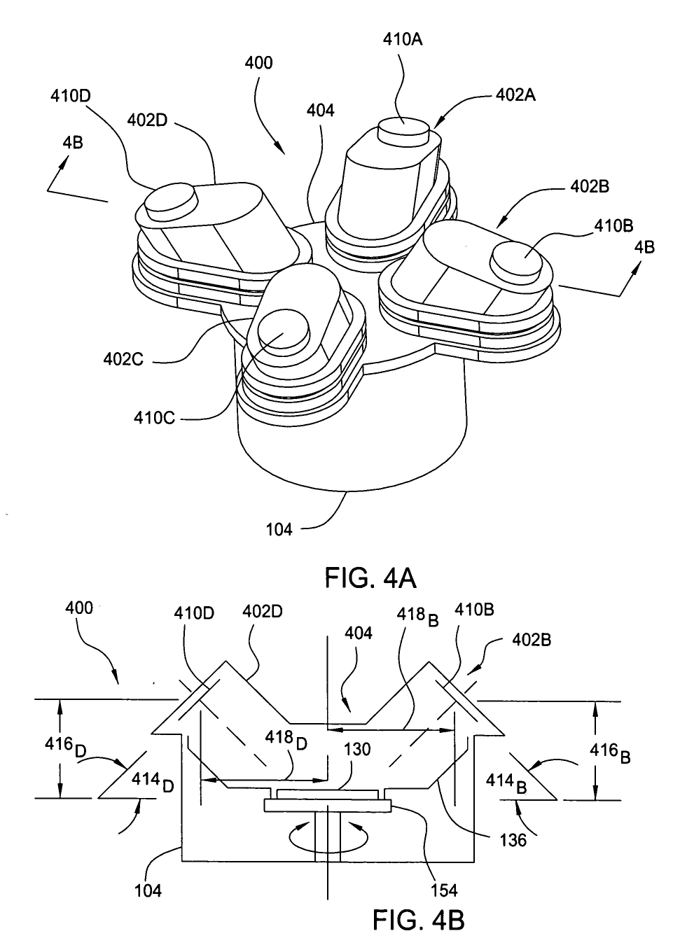

FIGS. 4A-B depict a schematic perspective and sectional views of another PVD chamber 400 comprising a plurality of the lid assemblies (four assemblies 402A-402D are illustratively shown) in accordance with yet another embodiment of the present invention. The image of FIG. 4A is simplified for illustrative purposes and is not depicted to scale. The lid assemblies 402A-D are similar to the lid assembly 202 described above. As such, the reader should refer simultaneously to FIGS. 2 and 4A-B.

Components that are substantially common to the PVD chambers 200 and 400 have been discussed above in reference to FIGS. 1-2. Herein, similar components are identified using same reference numerals, except that the alphabetical suffixes are added, when appropriate, to differentiate between specific devices.

In the PVD chamber 400, the lid assemblies 402A-D are disposed around the rotatable substrate pedestal 126 (shown in FIG. 4B) of the main assembly 104 upon a common flange 404. The common flange 404 is in vacuum-tight contacts with the lid assemblies 402A-D and the main assembly 104. In one embodiment, with respect to the substrate pedestal 126, the lid assemblies 402A-D are disposed on the flange 404 substantially symmetrically. In a further embodiment, spatial positions of each target assembly 410A-410D may be selectively optimized by adjustment of the respective lid assembly 402A-B, as discussed above in reference to the lid assembly 202 and target assembly 110 of FIG. 2.

The PVD chamber 400 allows further optimization of properties of the deposited films (e.g., achieving minimal thickness non-uniformity), as well as facilitates in-situ fabrication of complex film structures (e.g., magnetic random access memory (MRAM) structures, and the like). For example, the PVD chamber 400 where the target assemblies 410A-410D comprise targets 118 formed from different materials may be used to deposit in-situ multi-layered film stacks of highly uniform films of such materials or their mixtures. Moreover, as spatial positions (i.e., angles 414_{A-B}, heights 416_{A-B}, and offsets 418_{A-B}) of each target assembly 410_{A-D} in the apparatus 400 may be individually optimized relative to the rotating substrate pedestal 126 (i.e., angles 414_{A-B} may not necessarily be equal, with the same for heights 416_{A-B}, and offsets 418_{A-B}), different materials and film stacks may be in-situ deposited with minimal non-uniformity of the film thickness.

While the foregoing is directed to embodiments of the present invention, other and further embodiments of the invention may be devised without departing from the basic scope thereof, and the scope thereof is determined by the claims that follow.

1. A physical vapor deposition chamber, comprising:
a chamber body;
a rotatable substrate pedestal disposed in the chamber body; and
at least one sputtering target adjustable between different processing positions.

2. The chamber of claim 1, wherein the at least one sputtering target is non-parallel to a substrate supporting surface of the substrate pedestal.

3. The chamber of claim 1, wherein the target is disposed at an angle between about 0 to about 45 degrees.

4. The chamber of claim 1 further comprising:
a lid assembly disposed on the chamber body and having the sputtering target coupled thereto.

5. The chamber of claim 4, wherein the lid assembly is laterally movable between processing positions relative to the pedestal.

6. The chamber of claim 5 further comprising:
a plurality of sliders selectively extending from the chamber body and spacing the lid assembly from the chamber body.

7. The chamber of claim 5, wherein the target is disposed at an angle between about 0 to about 45 degrees.

8. The chamber of claim 4, wherein the lid assembly is vertically movable between processing positions relative to an axis of rotation of the pedestal.

9. The chamber of claim 8, wherein the target is disposed at an angle between about 0 to about 45 degrees.

10. The chamber of claim 1, wherein the at least one sputtering target is a plurality of targets disposed around the substrate pedestal.

11. The chamber of claim 10, wherein at least two of the sputtering targets are comprised of different materials.

12. The chamber of claim 1 further comprising:
a shield coupled to the chamber body and extending inwardly and downward toward the pedestal.

13. The chamber of claim 12 further comprising:
at least one substrate heating element disposed in a region of the chamber body below the shield.

14. The chamber of claim 13, wherein the shield interleaves with the pedestal.

15. The chamber of claim 14, wherein the substrate pedestal further comprises:
an annular peripheral upwardly facing trench.

16. The chamber of claim 15, wherein the pedestal further comprises:
an inner lip engaging the trench of the pedestal when the pedestal is in a raised position.

17. The chamber of claim 1, wherein the substrate pedestal further comprises:
a substrate supporting surface; and
an annular peripheral rim extending from the supporting surface and defining a substrate receiving pocket.

18. The chamber of claim 1, wherein the substrate pedestal further comprises:
a substrate supporting surface; and
at least one polymer member disposed in the supporting surface.

19. A physical vapor deposition chamber, comprising:
a chamber body;
a rotatable substrate pedestal disposed in the chamber body;
at least one target having a sputtering surface adjustable between processing positions, wherein the sputtering surface in at least one processing position is non-parallel to a substrate supporting surface of the pedestal; and
a lid assembly disposed on the chamber body and having the sputtering target coupled thereto.

20. The chamber of claim 20, wherein the sputtering surface of target is disposed at an angle to the supporting surface greater than about 0 to about 45 degrees.

21. The chamber of claim 19, wherein the lid assembly is laterally movable between processing positions relative to the pedestal.

22. The chamber of claim 21 further comprising:
a plurality of sliders selectively extending from the chamber body and spacing the lid assembly from the chamber body.

23. The chamber of claim 19, wherein the lid assembly is vertically movable between processing positions relative to an axis of rotation of the pedestal.

24. The chamber of claim 19, wherein the at least one target is a pluraliaty of targets disposed around the substrate pedestal.

25. The chamber of claim 24, wherein at least two of the sputtering targets are comprised of different materials.

26. The chamber of claim 20 further comprising:
a shield coupled to the chamber body and extending inwardly and downward toward the pedestal.

27. The chamber of claim 26 further comprising:
at least one substrate heating element disposed in a region of the chamber body below the shield.

28. The chamber of claim 27, wherein the shield interleaves with the pedestal.

29. The chamber of claim 28, wherein the substrate pedestal further comprises:
an annular peripheral upwardly facing trench.

30. The chamber of claim 29, wherein the shield further comprises:
an inner lip engaging the trench of the pedestal when the pedestal is in a raised position.

31. The chamber of claim 20, wherein the substrate pedestal further comprises:
a substrate supporting surface; and
an annular peripheral rim extending from the supporting surface and defining a substrate receiving pocket.

32. A physical vapor deposition chamber, comprising:
a chamber body;
a rotatable substrate pedestal disposed in the chamber body and having an upwardly orientated trench;
a shield coupled to the chamber body and extending inwardly and downward toward the pedestal and the trench of the pedestal when the pedestal is in a raised position;
a first drive coupled and adapted to rotate the substrate pedestal;
a second drive coupled to and adapted to control an elevation of the pedestal within the chamber body;
at least one target having a sputtering surface adjustable between processing positions, wherein the sputtering surface in at least one processing position is non-parallel to a substrate supporting surface of the pedestal; and
a lid assembly disposed on the chamber body and having the sputtering target coupled thereto.

33. The chamber of claim 32, wherein the sputtering surface of target is disposed at an angle to the supporting surface greater than about 0 to about 45 degrees.

34. The chamber of claim 32, wherein the lid assembly is laterally movable between processing positions relative to the pedestal.

35. The chamber of claim 34, wherein the lid assembly is vertically movable between processing positions relative to an axis of rotation of the pedestal.

36. The chamber of claim 35 further comprising:
a plurality of sliders selectively extending from the chamber body and spacing the lid assembly from the chamber body.

37. The chamber of claim 32, wherein the at least one target is a plurality of targets disposed around the substrate pedestal.

38. The chamber of claim 37, wherein at least two of the sputtering targets are comprised of different materials.

39. A method for physical vapor deposition, comprising:
performing a first physical vapor deposition process in a chamber having a target and substrate support disposed in a first orientation; and
performing a second physical vapor deposition in the chamber having a target and substrate supporting disposed in a second orientation.
